(19) United States
(12) Patent Application Publication
(10) Pub. No.: US 2021/0071312 A1
(43) Pub. Date: Mar. 11, 2021

(54) PLATING METHOD, PLATING APPARATUS, ANODE HOLDER

(71) Applicant: EBARA CORPORATION, Tokyo (JP)

(72) Inventors: Naoki Shimomura, Tokyo (JP); Mizuki Nagai, Tokyo (JP)

(73) Assignee: EBARA CORPORATION, Tokyo (JP)

(21) Appl. No.: 17/012,018

(22) Filed: Sep. 3, 2020

(30) Foreign Application Priority Data
Sep. 10, 2019 (JP) 2019-164344

(51) Int. Cl. C25D 17/10; H01L 21/288; C25D 7/12; C25D 17/00; C25D 17/08

(52) U.S. Cl. CPC C25D 17/10; H01L 21/288; C25D 17/08; C25D 17/001; C25D 7/12

(57) ABSTRACT

Provided is a plating method for improving in-plane uniformity of various square-shaped substrates without changing an inter-electrode distance. A plating method according to an aspect in which an anode holder (44) adapted to hold a square-shaped anode (62) and a substrate holder (24) adapted to hold a square-shaped substrate (W) are disposed to face each other and plating processing is performed on the substrate (W), the anode holder (44) includes a holder main body (80) having a square-shaped opening and adapted to hold the anode (62) with a surface of the anode (62) exposed from the opening, and a mask (88) adapted to cover a part of the anode (62) inside the opening, and a position covered with the mask (88) is changed in accordance with the substrate (W).

### CROSS-REFERENCE TO RELATED APPLICATION

This application claims the priority benefit of Japanese Application Serial No. 2019-164344, filed on Sep. 10, 2019. The entirety of the above-mentioned patent application is hereby incorporated by reference herein and made a part of this specification.

### BACKGROUND

### Technical Field

The present invention relates to a plating method, a plating apparatus, and an anode holder.

### Description of Related Art

As a method for forming a wiring and a bump (projecting electrode) in a circular substrate such as a semiconductor wafer, an electroplating method that is achieved with relatively low costs in a short processing time has widely been used. A plating apparatus used for the electroplating method includes a substrate holder adapted to hold a substrate in a state in which the surface thereof is exposed and an anode disposed to face the substrate. The substrate is connected to a power supply via the substrate holder, and the anode is connected to the power supply via an anode holder adapted to hold the anode. In plating processing, the entire substrate holder is immersed in a plating solution, and a current is caused to flow between the anode, which is similarly immersed in the plating solution, and the substrate, thereby accumulating a conductive material on the surface of the substrate.

In a case in which electroplating processing is performed on the surface of the substrate, the plating film is typically required to have a thickness that is as uniform as possible. Hereinafter, uniformity of the thickness of the plating film on the surface of the substrate will be referred to as “in-plane uniformity”. In order to obtain a substrate that has a film thickness with high in-plane uniformity, an electric field formed between the anode and the substrate has been controlled. Also, plating processing on square substrates, the demand for which has increased in recent years, has also been developed. According to Patent Document 1, for example, the shape of an anode mask provided at an anode holder is controlled.

### Patent Documents

[Patent Document 1] Japanese Patent Laid-Open No. 2019-056164

[Patent Document 2] Japanese Patent Laid-Open No. 2005-029863

However, no standards have been defined in regard to the dimensions of square substrates. Thus, substrates with various sizes are present. On the other hand, in a case in which electroplating is performed on a substrate, it is necessary to set the distance (inter-electrode distance) between the anode and the substrate to be an appropriate length in order to secure in-plane uniformity of the film thickness. Since the appropriate inter-electrode distance changes depending on the size or the like of the substrate, it is necessary to change the inter-electrode distance in a case in which plating is performed on different substrates, which is significantly troublesome. There is a concern that the film thickness may become non-uniform in a case in which the inter-electrode distance is shorter than the appropriate length, in particular. The non-uniformity of the film thickness cannot be eliminated by measures such as changing of the shape of the anode mask, which have been performed in the related art.

According to an aspect of the invention, it is thus possible to improve in-plane uniformity of various square substrates without changing inter-electrode distances.

### SUMMARY

According to an aspect of the present invention, there is provided a plating method. In the plating method, an anode holder adapted to hold a square-shaped anode and a substrate holder adapted to hold a square-shaped substrate are disposed to face each other in a plating tank, and plating processing is performed on the substrate. The anode holder has a holder main body having a square-shaped opening and adapted to hold the anode with a surface of the anode exposed from the opening and a mask adapted to cover a part of the anode inside the opening. A position covered with the mask is changed in accordance with the substrate.

According to another aspect of the present invention, there is provided a plating apparatus. The plating apparatus is adapted to perform plating processing on a square-shaped substrate. The plating apparatus includes a plating tank; an anode holder adapted to hold a square-shaped anode and disposed in a plating tank; and a substrate holder adapted to hold the substrate and disposed to face the anode in the plating tank. The anode holder has a holder main body having a square-shaped opening and adapted to hold the anode with a surface of the anode exposed from the opening and a mask adapted to cover a part of the anode inside the opening. The anode holder includes a drive unit adapted to drive the mask to change the position of the mask relative to the opening.

According to yet another aspect of the present invention, there is provided an anode holder. The anode holder is adapted to hold a square-shaped anode. The anode holder includes: a holder main body having a square-shaped opening and adapted to hold the anode with a surface of the anode exposed from the opening; a mask adapted to cover a part of the anode on an inner side beyond an end of the opening; and a drive unit adapted to drive the mask to change a position of the mask relative to the holder main body.

According to yet another aspect of the present invention, there is provided a plating apparatus. The plating apparatus is adapted to perform plating processing on a square-shaped substrate. The plating substrate includes: a plating tank; an anode holder adapted to hold a square-shaped anode and disposed in a plating tank; and a substrate holder adapted to hold the substrate and disposed to face the anode in the plating tank. The anode holder has a holder main body having a square-shaped opening and adapted to hold the anode with a surface of the anode exposed from the opening and a mask adapted to cover a part of the anode inside the opening. The substrate holder includes contact points placed along sides of the substrate to supply a current to the substrate. The mask extends parallel to power supply sides that are sides of the substrate, along which the contact points are aligned, and does not extend parallel to sides of the substrate that are not the power supply sides.

### BRIEF DESCRIPTION OF THE DRAWINGS

FIG. 1 is a plan view schematically illustrating a plating apparatus according to a first embodiment.

FIG. 2 is a diagram illustrating an overview of a plating tank.

FIG. 3 is a perspective view illustrating a configuration of an anode holder.

FIG. 4 is an exploded perspective view illustrating the configuration of the anode holder.

FIG. 5 is a sectional view along A-A in FIG. 4.

FIG. 6 is a perspective view of a substrate holder.

FIG. 7 is an exploded perspective view of the substrate holder.

FIG. 8 is a sectional view along B-B in FIG. 6.

FIG. 9 is a conceptual diagram illustrating a positional relationship of the anode holder, an intermediate mask, and the substrate holder.

FIG. 10 is graph illustrating the thickness of a plating film.

FIG. 11 is front view of anode holders according to modification examples of the first embodiment.

FIG. 12 is a front view of an anode holder according to a modification example of the first embodiment.

FIG. 13 is a perspective view of an anode holder according to a second embodiment.

FIG. 14 is front view of an anode holder according to a modification example of the second embodiment.

### DESCRIPTION OF THE EMBODIMENTS

Hereinafter, embodiments will be described with reference to drawings. Note that the same reference signs will be applied to substantially the same components in the following embodiments and modification examples thereof, and description thereof will appropriately be omitted.

### First Embodiment

According to an aspect of the present invention, it is possible to improve in-plane uniformity of various square-shaped substrates without changing inter-electrode distances.

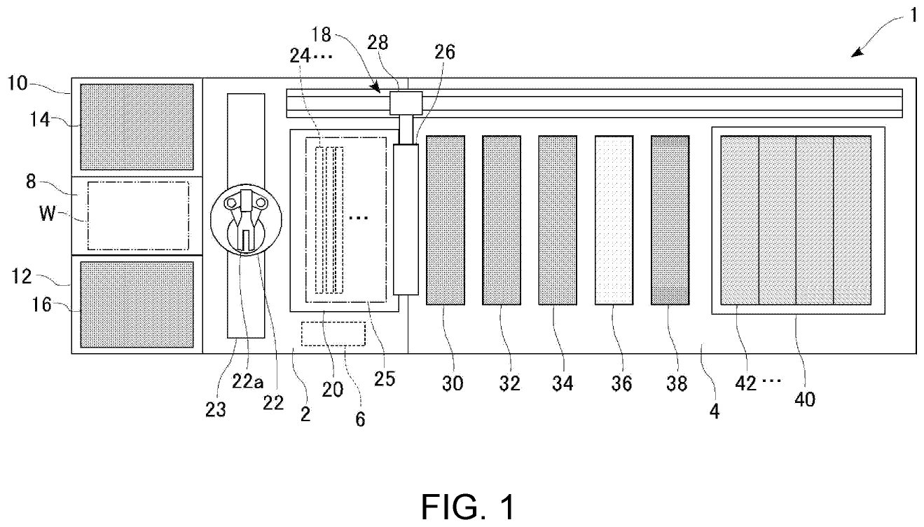

FIG. 1 is a plan view schematically illustrating a plating apparatus 1 according to a first embodiment.

The plating apparatus 1 includes a substrate attachment/detachment unit 2, a plating processing unit 4, and a control unit 6. The plating apparatus 1 according to this embodiment is a bump plating apparatus for forming projecting electrodes (bumps) on a substrate. A substrate passing table 8 is provided in front of the substrate attachment/detachment unit 2, and a pre-washing unit 10 and a post-washing unit 12 are provided to be adjacent to the substrate passing table 8. Note that although an apparatus for passing a substrate, on which processing has been performed in upstream processes, to the substrate passing table 8 is provided in front of the plating apparatus 1, description thereof will be omitted.

The substrate passing table 8 is adapted such that a substrate W is placed thereon in a horizontal posture. The substrate W is a relatively large thin substrate and is likely to be bent. In this embodiment, a rectangular substrate with a length of one side of about 500 mm is used as the substrate W. The substrate W includes a copper seed layer provided on the surface thereof, and a resist pattern is formed thereon.

The pre-washing unit 10 has a washing device 14 to perform pre-washing for removing organic substances and the like adhering to the surface of the substrate W prior to plating processing. The post-washing unit 12 has a washing device 16 to wash the substrate W that has detached from the substrate holder 24 after the plating processing. A holder transport mechanism 18 is provided from the substrate attachment/detachment unit 2 to the plating processing unit 4. The control unit 6 controls operations of each of components.

The substrate attachment/detachment unit 2 includes an attachment/detachment mechanism 20, a substrate transport robot 22, and a moving mechanism 23. The substrate transport robot 22 has a robot hand 22a. The substrate transport robot 22 functions as a “substrate transport unit” to pass the substrate W to the substrate passing table 8 and receive the substrate W therefrom and to pass the substrate W to each mechanism and receive the substrate W therefrom. The robot hand 22a has a non-contact chuck for holding the substrate W in a horizontal posture.

The moving mechanism 23 is adapted to move the substrate transport robot 22 in accordance with a passing position of the substrate W. The substrate transport robot 22 moves to the vicinity of the pre-washing unit 10 in the pre-washing process and moves to the vicinity of the post-washing unit 12 in the post-washing process.

A stocker 25 for storing the substrate holder 24 is provided below the attachment/detachment mechanism 20. The attachment/detachment mechanism 20 is adapted to attach the substrate W to the substrate holder 24 and detach the substrate W therefrom. The holder transport mechanism 18 has a gripping mechanism 26 adapted to grip the substrate holder 24 and a transport mechanism 28 adapted to transport the substrate holder 24 to each tank of the plating processing unit 4. The attachment/detachment mechanism 20 is adapted to attach the substrate holder 24 to the gripping mechanism 26 and detach the substrate holder 24 therefrom.

The plating processing unit 4 has a pre-wetting tank 30, a pre-soaking tank 32, a rinsing tank 34, a blowing tank 36, a rinsing tank 38, and an overflow tank 40 in this order from the side of the substrate attachment/detachment unit 2. Plating tanks 42 in a plurality of lines are provided inside the overflow tank 40. The pre-wetting tank 30 can also fill the inside of a resist opening on the surface of the substrate with degassed water by immersing the substrate W in the degassed water and wetting the substrate W with the degassed water. The pre-soaking tank 32 is adapted to remove, through etching, an oxide film generated on the surface of the substrate W with a chemical solution.

The rinsing tanks 34 and 38 are adapted to wash the surface of the substrate W with deionized water. The rinsing tank 34 is adapted to perform water washing prior to the plating processing while the rinsing tank 38 is adapted to perform water washing after the plating processing. The blowing tank 36 is adapted to drain water off from the substrate W after the washing. A plating solution is stored in the plating tanks 42. Plating can be applied by immersing the substrate W in the plating tanks 42 and circulating the plating solution while causing the plating solution to overflow to the overflow tank 40. Typically, a processing time of the plating processing is relatively longer than that of other processing such as washing and drying. Therefore, the plurality of tanks 42 are provided so as to be able to perform the plating processing on a plurality of substrates W at the same time in parallel.

The transport mechanism 28 is a mechanism based on a linear motor scheme, for example, and transports the substrate holder 24 to each tank of the plating processing unit 4. The transport mechanism 28 successively transports the substrate holder 24 using a time lag of the processing in each plating tank 42.

The control unit 6 is configured of a microcomputer and includes a CPU adapted to execute various kinds of arithmetic operation processing, a ROM adapted to store a control program and the like, a RAM used as a work area for storing data and executing the program, a non-volatile memory adapted to hold stored details even after power supply is interrupted, an input/output interface, a time counting timer, and the like. Note that although the control unit 6 is adapted to drive and control each mechanism in this embodiment, each mechanism may be provided with a control unit. In this case, a collective control unit adapted to collectively manage the control unit of each mechanism may be provided.

With the configuration as described above, the plating apparatus 1 performs the operations schematically described below.

First, the substrate transport robot 22 takes the substrate W as a plating target out of the substrate passing table 8 and sets the substrate W in the washing device 14. The washing device 14 receives the substrate W and then executes the pre-washing processing thereon for removing organic substances and the like. When the pre-washing ends, the substrate transport robot 22 receives the substrate W from the washing device 14 and passes the substrate W to the attachment/detachment mechanism 20. The attachment/detachment mechanism 20 sets the substrate W in the substrate holder 24 and attaches the substrate W to the gripping mechanism 26.

The transport mechanism 28 lifts up the gripping mechanism 26, transports the substrate holder 24, and immerses the substrate W along with the substrate holder 24 in the pre-wetting tank 30. In this manner, pre-wetting processing using degassed water is performed. Note that although the degassed water is stored in the pre-wetting tank 30 in this embodiment, the present invention is not necessarily limited thereto as long as it is possible to replace air in the resist opening on the surface of the substrate and to perform the pre-wetting processing for filling the inside of the resist opening with the solution as well.

Note that, the pre-wetting tank 30 may not be provided as long as pre-wetting processing can sufficiently be performed by the washing device 14.

The transport mechanism 28 then takes the substrate holder 24 out of the pre-wetting tank 30, transports the substrate holder 24, and immerses the substrate holder 24 in the pre-soaking tank 32. A chemical solution such as sulfuric acid or hydrochloric acid is stored in the pre-soaking tank 32. In a case in which an oxide film has been generated on the seed layer (conductive layer) of the substrate W, the oxide film is removed through the pre-soaking processing using the chemical solution. In this manner, it is possible to expose a clean metal surface of the seed layer.

The transport mechanism 28 then takes the substrate holder 24 out of the pre-soaking tank 32, transports the substrate holder 24, and immerses the substrate holder 24 in the rinsing tank 34. In this manner, the chemical solution adhering to the substrate W is washed off with deionized water. The transport mechanism 28 then immerses the substrate W in a vacant plating tank 42. Note that although copper plating is performed in this plating processing in this embodiment, it is also possible to perform other kinds of plating such as nickel or gold plating by changing the plating solution to be supplied to the plating tank 42.

The substrate W on which plating has been performed in this manner is washed in the rinsing tank 38, and water is then drained therefrom in the blowing tank 36. Thereafter, the substrate W is transported to the attachment/detachment mechanism 20. The attachment/detachment mechanism 20 detaches the substrate holder 24 from the gripping mechanism 26 and takes the substrate W out of the substrate holder 24. The substrate transport robot 22 receives the substrate W from the attachment/detachment mechanism 20 and sets the substrate W in the washing device 16. The washing device 16 receives the substrate W and then executes the post-washing processing thereon.

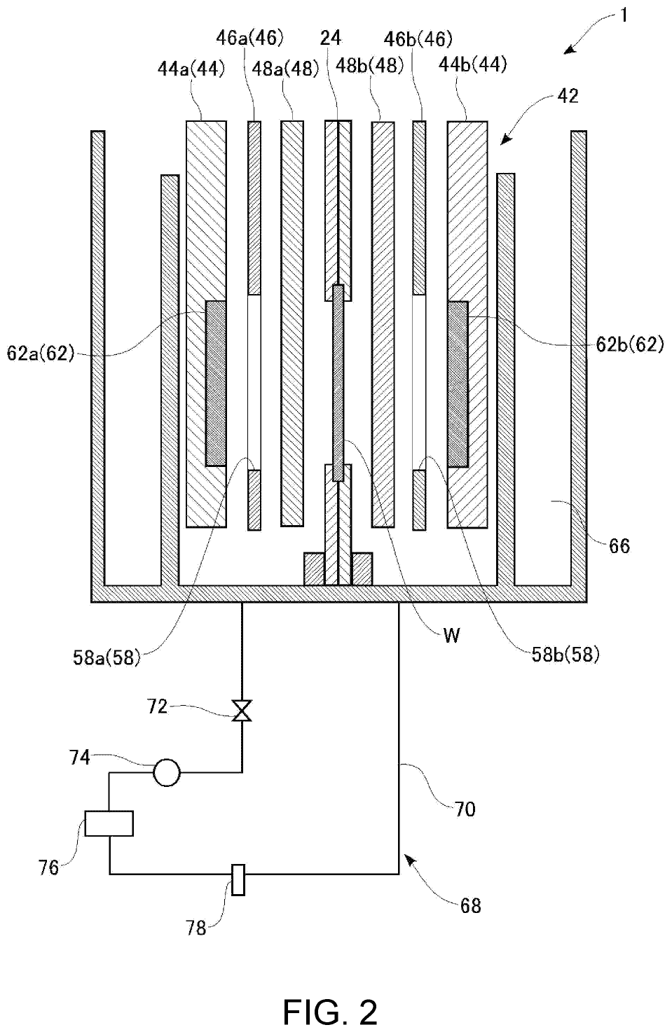

FIG. 2 is a diagram illustrating an overview of one of the plating tank 42. In this embodiment, the plating is performed on both surfaces of the substrate W. A first anode holder 44a, a first intermediate mask 46a, a first paddle 48a, a substrate holder 24, a second paddle 48b, a second intermediate mask 46b, and a second anode holder 44b are included in the plating tank 42. A first anode 62a is held by the first anode holder 44a. The first anode 62a is connected to an external power supply via a wiring in the first anode holder 44a. Also, a second anode 62b is held by the second anode holder 44b. The second anode 62b is connected to an external power supply via a wiring in the second anode holder 44b. The substrate W is held by the substrate holder 24. During the plating processing, the first anode holder 44a is disposed to face a first surface (front surface) of the substrate W, and the second anode holder 44b is disposed to face a second surface (rear surface) of the substrate W.

The first intermediate mask 46a is provided between the first anode holder 44a and the substrate holder 24. The first intermediate mask 46a is provided with a first opening 58a. An electric field between the first intermediate mask 46a and the substrate W is adjusted by adjusting the size of the first opening 58a. A first paddle 48a for stirring the plating solution in the vicinity of the surface of the substrate W is provided between the first anode holder 44a and the substrate holder 24. The first paddle 48a is a bar-shaped member, for example, and is provided inside the plating tank 42 to as to be directed in the vertical direction. The first paddle 48 is configured to be able to be moved parallel to both the surfaces of the substrate W by a drive device, which is not illustrated.

Also, the second intermediate mask 46b is provided between the second anode holder 44b and the substrate holder 24. The second intermediate mask 46b is provided with a second opening 58b. An electric field between the second intermediate mask 46b and the substrate W is adjusted by adjusting the size of the second opening 58b. A second paddle 48b for stirring the plating solution in the vicinity of the rear surface of the substrate W is provided between the second anode holder 44b and the substrate holder 24. The second paddle 48b is a bar-shaped member, for example, and is provided in the plating tank 42 so as to be directed in the vertical direction. The second paddle 48b is configured to be able to be moved parallel to both the surfaces of the substrate W by a drive device, which is not illustrated.

When a voltage is applied between the first anode 62a and the substrate W from an external power supply, a current flows in a route from the external power supply back to the external power supply through the first anode 62a, the plating solution, and the substrate W. Also, when a voltage is applied between the second anode 62b and the substrate W from the external power supply, a current flows in a route from the external power supply back to the external power supply through the second anode 62b, the plating solution, and the substrate W. Copper plating is performed on both the surfaces of the substrate W with these currents.

An external tank 66 adapted to receive the plating solution overflowing from the plating tank 42 is provided in the outer periphery of the plating tank 42. The plating apparatus 1 includes a circulation mechanism 68 adapted to circulate the plating solution between the plating tank 42 and the external tank 66. The circulation mechanism 68 includes a circulation line 70 connecting the external tank 66 to the plating tank 42. The circulation line 70 is provided with a valve 72, a pump 74, a temperature control device 76, and a filter 78.

Hereinafter, the first anode holder 44a and the second anode holder 44b will simply be referred to as an anode holder 44, and no identifiers will be applied thereto, in a case in which the first anode holder 44a and the second anode holder 44b are not distinguished from each other, in particular. Similarly, the first opening 58a and the second opening 58b, the first intermediate mask 46a and the second intermediate mask 46b, the first paddle 48a and the second paddle 48b, and the first anode 62a and the second anode 62b will be referred to as an opening 58, an intermediate mask 46, a paddle 48, and an anode 62. Note that the anode holder 44, the intermediate mask 46, and the substrate holder 24 are disposed to face each other as illustrated in FIG. 2.

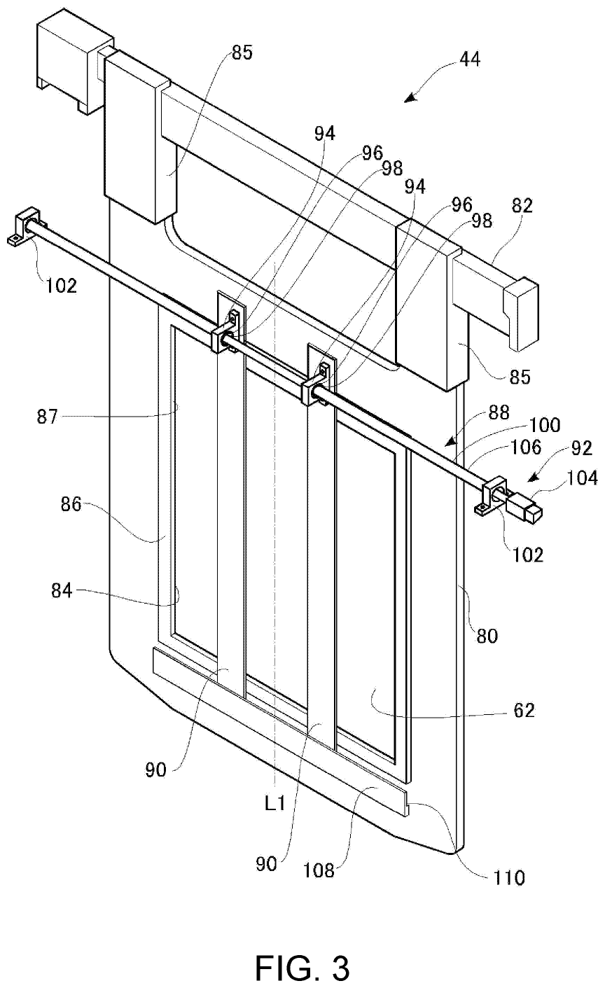

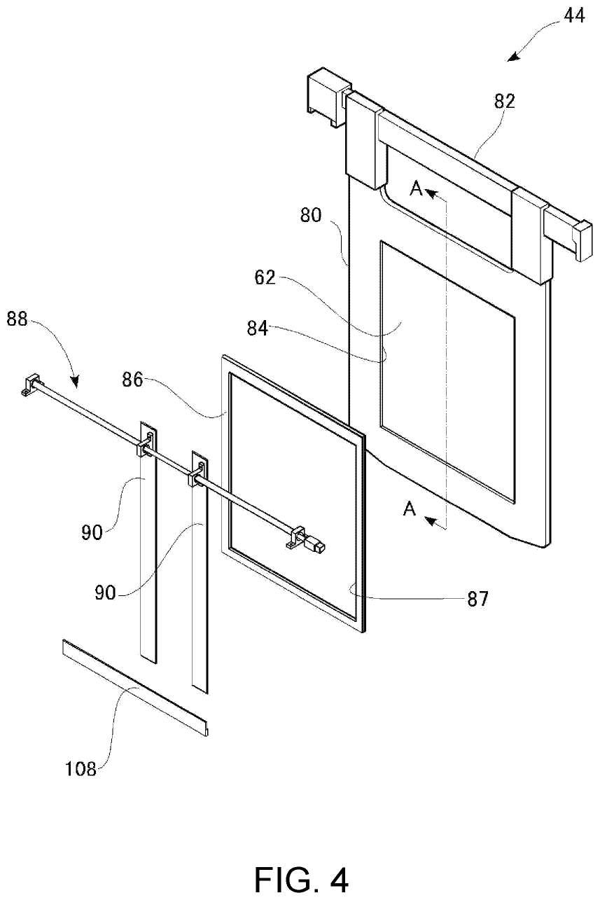

FIG. 3 is a perspective view illustrating a configuration of the anode holder 44. FIG. 4 is an exploded perspective view illustrating the configuration of the anode holder 44.

As illustrate in FIG. 3, the anode holder 44 includes a holder main body 80 with a substantially rectangular shape and an arm unit 82 with a rectangular shape. The holder main body 80 has an opening 84. The holder main body 80 is configured to hold the anode 62 and to expose the surface of the anode 62 from the opening 84. The arm unit 82 is provided above the holder main body 80, and a coupling unit 85 coupling an upper end of the holder main body 80 to the arm unit 82 is provided therebetween. The holder main body 80 is disposed in the plating apparatus 1 (see FIG. 2) in such a form in which both ends of the arm unit 82 are supported by the upper surface of the plating tank 42 (see FIG. 2). Also, a power supply terminal (not illustrated) electrically connected to an external electrode provided on the upper surface of the plating tank 42 is provided at the end of the arm unit 82.

A frame-shaped anode mask 86 is provided in the peripheral edge of the opening 84. The anode mask 86 is made of a dielectric material and is provided in a surface of the anode holder 44 facing the substrate holder 24 (see FIG. 2). The anode mask 86 has an opening 87 that is smaller than the opening 84 and is provided in such a form to cover the outer peripheral edge of the anode 62 in front of the anode holder 44.

The anode holder 44 includes a mask unit 88 (mask) for adjusting the thickness of the plating film in addition to the anode mask 86. The mask unit 88 includes two mask members 90 with strip shapes and a drive mechanism 92. In this embodiment, the mask members 90 extend parallel to the left side (right side) of the opening 84 in such a form in which the upper side and the lower side of the opening 84 are bridged. The width of the mask members 90 is 5 mm to 100 mm, for example, and is preferably 10 mm to 50 mm.

Guide members 94 are provided at upper ends of the mask members 90. The guide members 94 are provided with through-holes 96 in a direction that perpendicularly intersects the extending direction of the mask members 90, and female screws 98 are formed in inner peripheral surfaces thereof. The drive mechanism 92 includes a rod 100, a pair of bearings 102, and a motor 104. Male screws 106 are formed in the outer peripheral surface of the rod 100. The rod 100 is inserted into the two through-holes 96, and the female screws 98 and the male screws 106 are screwed to each other, thereby configuring a screw feeding mechanism. The rod 100 is supported by the pair of bearings 102, and an end thereof is connected to a rotation shaft of the motor 104.

The motor 104 and the bearings 102 are secured to each plating tank 42 (see FIG. 42). The two guide members 94 move in mutually opposite directions relative to the axial direction of the rod 100 in response to rotation of the rod 100. The two guide members 94 are provided at symmetric positions relative to the center of the upper side (lower side) of the opening 84. In other words, the two guide members 94 approach and are separated from the center line L1 of the opening 84 corresponding to a direction that passes through the center of the opening 84 and is perpendicular to the axial line of the rod 100 in response to rotation of the rod 100. In this manner, the two mask members 90 approach and are separated from each other in response to the rotation of the rod 100.

A guide 108 extending parallel to the axial direction of the rod 100 is provided at a lower portion of the holder main body 80 (below the opening 84). A slit 110 is formed between the guide 108 and the holder main body 80. The lower end of the mask member 90 is inserted into the slit 110 and is moved along the guide 108.

As illustrated in FIG. 4, the anode holder 44 is configured such that the holder main body 80, the anode mask 86, the mask unit 88, and the guide 108 overlap each other in this order from the rear surface to the front surface. The anode 62 is held at the opening 84 of the anode holder 44. Hereinafter, a positional relationship between the anode holder 44 and the anode 62 will be described.

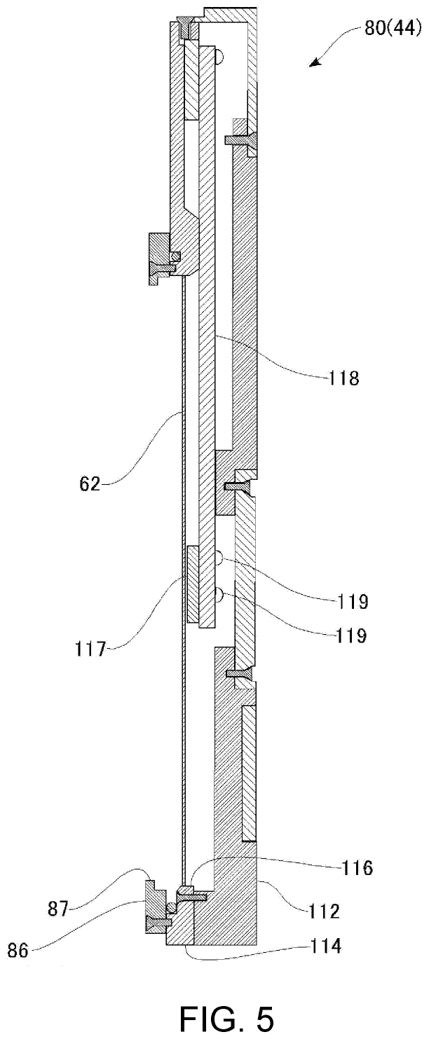

FIG. 5 is a sectional view along A-A in FIG. 4.

The holder main body 80 (the anode holder 44) has a holder base 112 with a substantially rectangular shape and a holder base cover 114 adapted to partially cover the front surface of the holder base 112.

An opening 116 with substantially the same size as that of the anode 62 is formed at substantially the center of the holder base cover 114. One surface of the anode 62 is exposed from the opening 116. The holder base cover 114 is screwed to the holder base 112. In this manner, tight adhesion is established at a coupling portion between the holder base cover 114 and the holder base 112.

The holder main body 80 has a power supply member 118 extending from the power supply terminal (not illustrated) to a portion between the holder base 112 and the holder base cover 114. The power supply member 118 is a conductive member with a substantially plate shape and is electrically connected to the power supply terminal.

The anode 62 is secured to the front surface of the power supply member 118 via an anode contact point 117. The anode 62 and the anode contact point 117 are secured to the power supply member 118 with a securing member 119 configured of a screw. In this manner, it is possible to apply a voltage from an external power supply to the anode 62 via the power supply terminal, the power supply member 118, and the anode contact point 117.

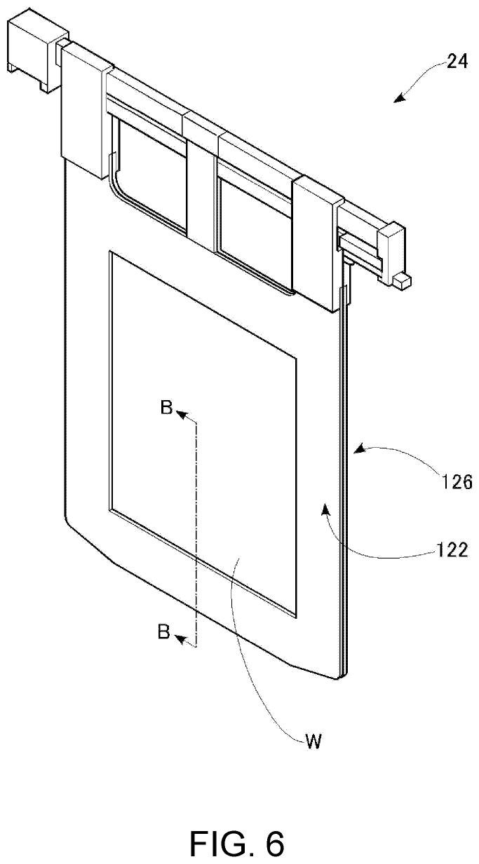

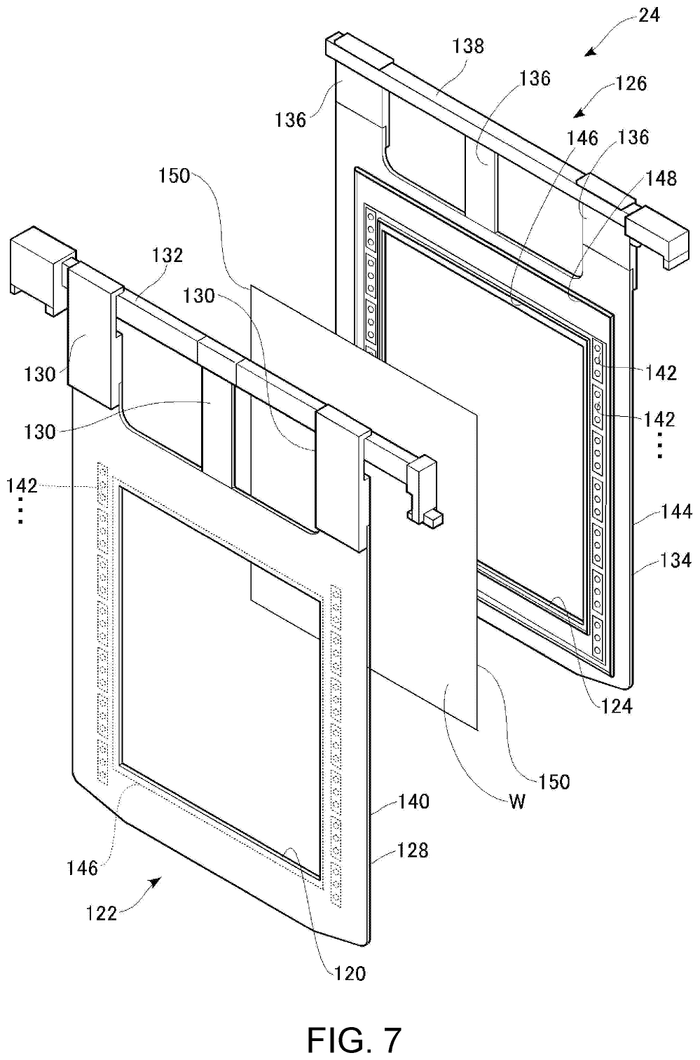

FIG. 6 is a perspective view of the substrate holder 24. FIG. 7 is an exploded perspective view of the substrate holder 24.

The substrate holder 24 includes a first holding member 122 and a second holding member 126. The first holding member 122 and the second holding member 126 are formed of metal such as Ti, for example, and includes an insulating coating applied to the surface thereof. As illustrated in FIG. 6, the substrate W is held by the substrate holder 24 in such a form in which it is interposed between the first holding member 122 and the second holding member 126.

As illustrated in FIG. 7, the first holding member 122 has a first opening 120, and the second holding member 126 has a second opening 124. The substrate W is held by the first holding member 122 and the second holding member 126 such that the plated surfaces on the front side and the rear side are exposed through the first opening 120 and the second opening 124. In other words, the first holding member 122 and the second holding member 126 hold the substrate W in such a form in which the only the outer peripheral portion of the substrate W is pinched from both sides. Note that the first opening 120 and the second opening 124 have the same shape in this embodiment.

The first holding member 122 includes a first main body unit 128 with a frame shape in which the first opening 120 is formed, three first coupling units 130, and a first arm unit 132. The first arm unit 132 is disposed above the first main body unit 128, and both the first main body unit 128 and the first arm unit 132 are bridged with the three first coupling units 130. The second holding member 126 includes a second main body unit 134 with a frame shape in which the second opening 124 is formed, three second coupling units 136, and a second arm unit 138. The second holding member 126 is also adapted such that the second arm unit 138 is disposed above the second main body unit 134 and both the second main body unit 134 and the second arm unit 138 are bridged with the three second coupling units 136.

Wirings, which are not illustrated, are stored in the first coupling unit 130 and the second coupling unit 136. The substrate holder 24 is brought into the state illustrated in FIG. 6 by the first arm unit 132 and the second arm unit 138 being engaged with each other.

The first main body unit 128 includes a first main body 140 with a frame shape, an inner seal 146 with a frame shape, and a substrate contact point 142. The inner seal 146 and the substrate contact point 142 are provided in a surface of the first main body unit 128 facing the second holding member 126. The second main body unit 134 includes a second main body 144 with a frame shape, a substrate contact point 142, an inner seal 146 with a frame shape, and an outer seal 148 with a frame shape. The substrate contact point 142, the inner seal 146, and the outer seal 148 are provided in a face of the second main body 144 facing the first holding member 122.

The inner seals 146 are provided in the first main body 140 and the second main body 144 in a form in which they follow the first opening 120 and the second opening 124. The outer seal 148 is provided in the second main body 144 in a form in which it surrounds the inner seal 146. The substrate contact points 142 are provided in the outer periphery of the inner seals 146. When the first holding member 122 and the second holding member 126 pinch the substrate W, the inner seals 146 and the substrate contact points 142 abut on the substrate W. Also, the outer seal 148 abuts on the first main body 140. In this manner, the substrate contact points 142 are surrounded by the inner seals 146, the outer seal 148, the first main body 140, and the second main body 144.

The first coupling unit 130 and the second coupling unit 136 store a plurality of wirings (not illustrated) for supplying electric power from an external power supply to the substrate contact points 142. As a method for supplying the electric power from the external power supply to the substrate contact points 142 and the like, known techniques disclosed in Japanese Patent Laid-Open No. 2019-7075, for example, can be employed.

In this embodiment, the plurality of substrate contact points 142 are provided in the first main body 140 and the second main body 144 in such a form in which the substrate contact points 142 follow sides in directions extending in the up-down direction of the first opening 120 and the second opening 124. In other words, the substrate contact points 142 are disposed in two lines along the vertical sides of each of the first opening 120 and the second opening 124. Hereinafter, the sides of the substrate W which the substrate contact points 142 follow will be referred to as “power supply sides 150”.

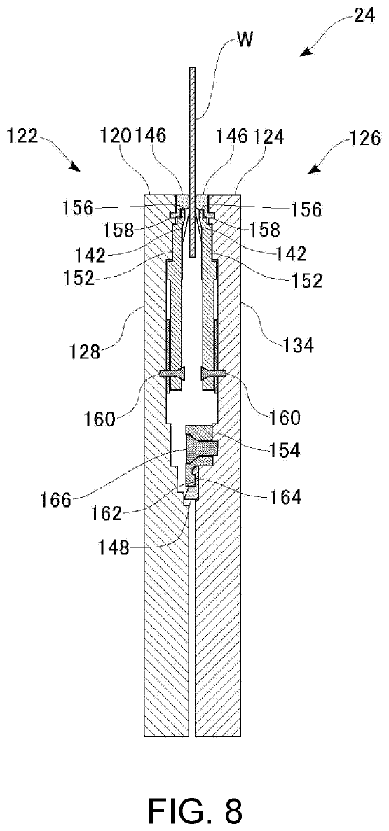

FIG. 8 is a sectional view along B-B in FIG. 6.

Seal holders 152 and 154 are provided between the first main body unit 128 and the second main body unit 134. The two seal holders 152 are adapted to secure the two inner seals 146 to the first main body 140 and the second main body 144, respectively. Step difference portions 156 are provided in the outer peripheral surfaces of the inner seals 146. A step difference portion 158 is also provided at an end of the seal holder 152. The step difference portions 156 and the step difference portion 158 have mutually complementary shapes. The inner seals 146 and the seal holder 152 are engaged with each other in a form in which the step difference portions 156 and the step difference portion 158 abut on each other.

The two seal holders 152 are secured to the first main body unit 128 and the second main body unit 134, respectively, with screws 160. With this structure, the inner seals 146 are secured to the first main body 140 and the second main body 144 with the seal holders 152.

The seal holder 154 is adapted to secure the outer seal 148 to the second main body 144. A step difference portion 162 is provided at an end of the outer seal 148. A step difference portion 164 is also provided at an end of the seal holder 154. The step difference portion 162 and the step difference portion 164 have mutually complementary shapes. The outer seal 148 and the seal holder 154 are engaged with each other in such a form in which the step difference portion 162 and the step difference portion 164 abut on each other. The seal holder 154 is secured to the second main body unit 134 with a screw 166. With this structure, the outer seal 148 is secured to the second main body 144 with the seal holder 154.

The substrate W abuts on the inner seals 146. Also, the outer seal 148 secured to the second main body 144 abuts on the first main body 140. The substrate contact points 142 abut on the substrate W between the inner seals 146 and the outer seal 148. In other words, the substrate contact points 142 are stored in a space with sealing properties secured by the inner seals 146 and the outer seal 148. With this configuration, the substrate contact points 142 are not brought into contact with the plating solution even in a case in which the substrate holder 24 is immersed to the plating solution in the plating tank 42 (see FIG. 2).

Note that as described above in relation to FIG. 7, the first opening 120 and the second opening 124 have the same shapes. As illustrated in FIG. 8, the first opening 120 and the second opening 124 are located at the same heights of the substrate holder 24. In other words, the first opening 120 and the second opening 124 overlap each other in the direction that is perpendicular to the substrate W (in the transverse direction in FIG. 8).

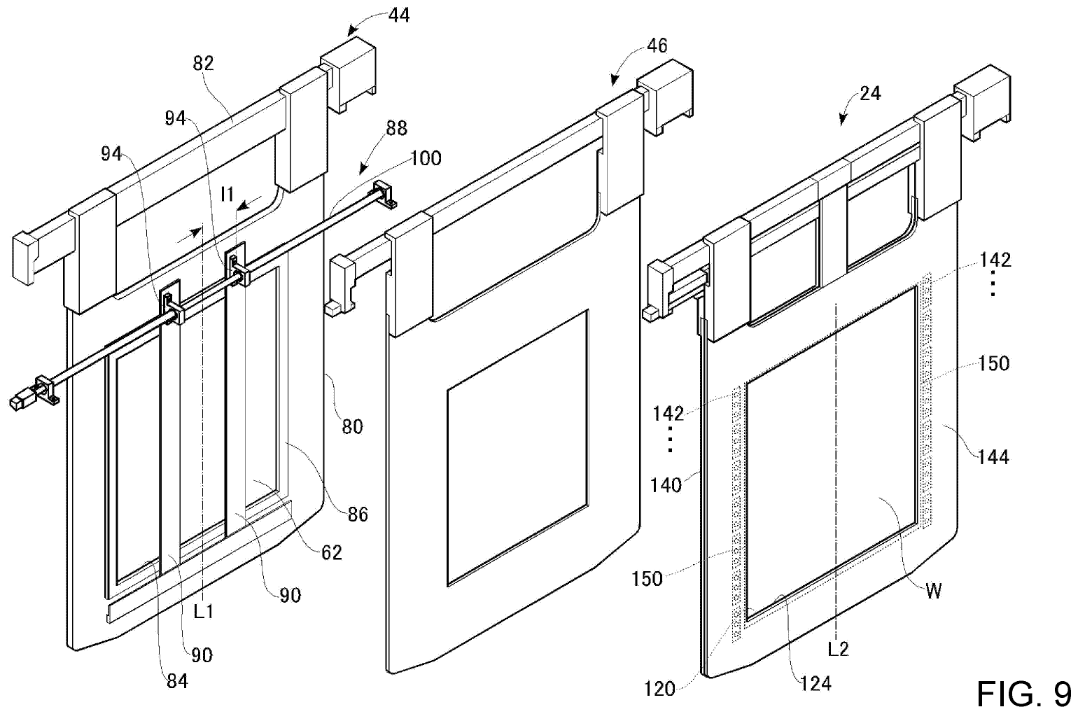

FIG. 9 is a conceptual diagram illustrating a positional relationship of the anode holder 44, the intermediate mask 46, and the substrate holder 24.

As described above in relation to FIGS. 3 and 4, the mask unit 88 is disposed in the anode holder 44. The mask members 90 extend in the up-down direction relative to the anode holder 44. Also, as describe above in relation to FIG. 7, the substrate contact points 142 (power supply sides 150) are disposed in the longitudinal direction of the first opening 120 and the second opening 124. In other words, the extending directions of the two mask members 90 and the power supply sides 150 in two lines are parallel to each other as illustrated in FIG. 9.

As described above in relation to FIG. 3, the two mask members 90 approach and are separated from each other in response to rotation of the rod 100. At this time, the two mask members 90 are provided at symmetric positions relative to the center line L1. The positions of the mask members 90 are covering positions against an electric field from the anode 62 toward the substrate W. As illustrated in FIG. 9, the distance from the center line L1 to the center of each mask member 90 is defined as a distance l1. Also, a line that passes through the center of the first opening 120 (second opening 124) and is parallel to the longitudinal sides of the first opening 120 (second opening 124) is defined as a center line L2. When the anode holder 44 and the substrate holder 24 are caused to face each other, the projection position of the center line L1 and the projection position of the center line L2 conform to each other in the direction in which the anode holder 44 (substrate holder 24) is viewed from the front side.

Here, a difference in film thickness of the substrate W depending on presence of the mask members 90 will be described.

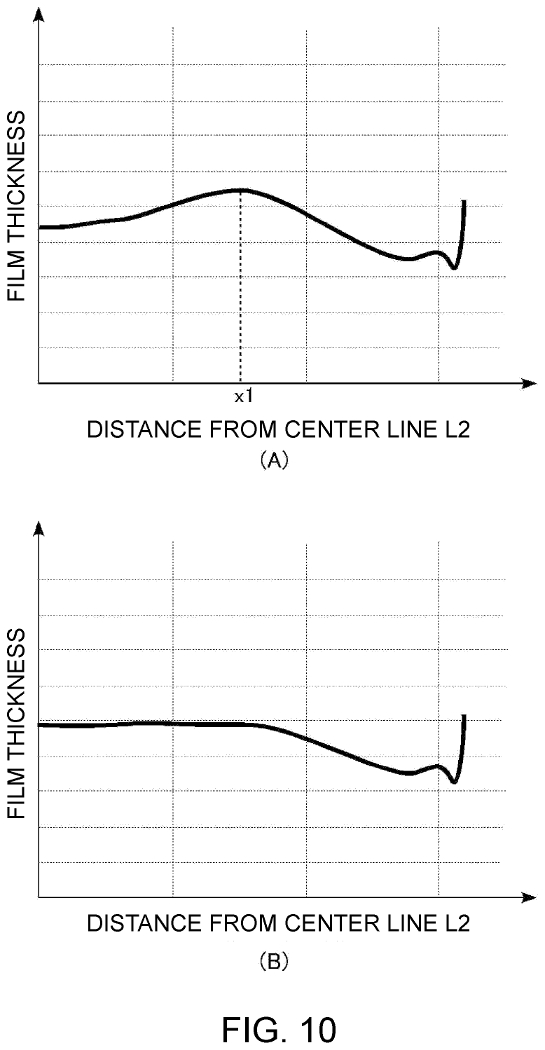

FIG. 10 is graph illustrating a thickness of the plating film with respect to the distance from the center line L2 to the power supply sides 150. (A) of FIG. 10 illustrates a case in which the mask members 90 are not disposed in the anode holder 44, and (B) of FIG. 10 illustrates a case in which the mask members 90 are disposed in the anode holder 44. In both (A) and (B) of FIG. 10, the distance (inter-electrode distance) between the anode 62 and the substrate W is set to be shorter than an optimal distance.

In a case in which the inter-electrode distance is shorter than the optimal distance as illustrated in (A) of FIG. 10, the film thickness of the substrate W increases at a point x1 that is a position at which the substrate W is separated from the power supply sides 150, from the center line L2 to the power supply sides 150. Such a local irregularity of film thickness is not improved even by changing the size of the opening 87 (see FIG. 9) of the anode mask 86.

In this embodiment, the mask members 90 (see FIG. 9) are provided at positions at which the mask members 90 face the locations where such irregularity of film thickness occurs. In other words, the distance l1 is set to the length x1. Then, the irregularity of the film thickness of the substrate W from the center line L2 to the power supply sides 150 is eliminated, and in-plane uniformity is improved, as illustrated in (B) of FIG. 10.

Since two power supply sides 150 are present in this embodiment, the irregularity of the film thickness illustrated by the graph in (A) of FIG. 10 is generated in the direction from the center line L2 illustrated in FIG. 9 to each of the power supply sides 150. In other words, the irregularity of the film thickness is generated at two locations of the substrate W. Since it is necessary to provide the mask members 90 at the locations where the irregularity of the film thickness is generated relative to each of the power supply sides 150, two mask members 90 are provided in a single anode holder 44 in this embodiment. Note that it is not necessary to strictly set the distance l1 to x1. It is only necessary to dispose the mask members 90 at positions at which the irregularity of the film thickness is curbed.

In this embodiment, the mask members 90 are provided to curb the irregularity of the film thickness of the substrate W illustrated in (A) of FIG. 10. In other words, if the mask members 90 are disposed at positions corresponding to locations other than the locations where the film thickness increases, there is a concern that the film thickness at the portions decreases and in-plane uniformity is rather degraded. In a case in which the number of the power supply sides 150 is two, the mask members 90 are not caused to extend parallel to two sides other than the power supply sides of the substrate W.

In a case in which inter-electrode distances are the same, the locations and degrees of the irregularity of the film thickness typically change depending on the size, the type, and the like of the substrate W. In this embodiment, the positions of the mask members 90 can be changed by the drive mechanism 92. It is possible to curb the irregularity of the film thickness of the substrate W that may have various sizes or the like, by configuring the mask unit 88 in this manner. It is thus possible to improve in-plane uniformity of various substrates W.

As described above, according to this embodiment, it is possible to improve in-plane uniformity of the film thickness by providing the two mask members 90 at equal distances from the center line L1 and at the positions corresponding to the locations where the irregularity of the film thickness of the substrate W is generated, in a case in which the inter-electrode distance is shorter than the optimal distance.

Also, according to this embodiment, it is possible to improve in-plane uniformity of the film thickness of various substrates W without changing the inter-electrode distance by changing the positions of the mask members 90. Thus, it is possible to minimize the size of each plating tank 42 (see FIG. 2) and to realize space saving.

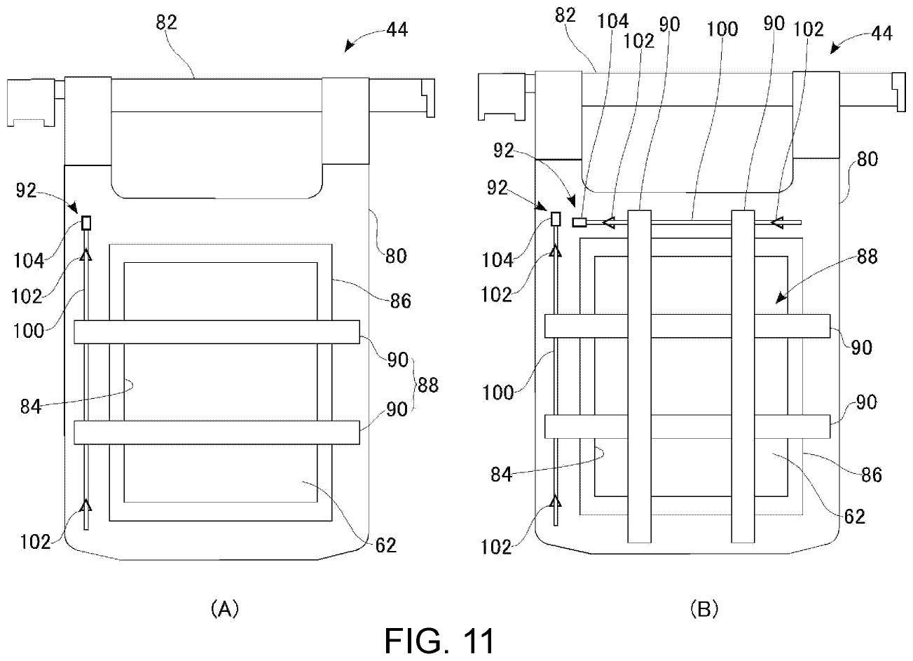

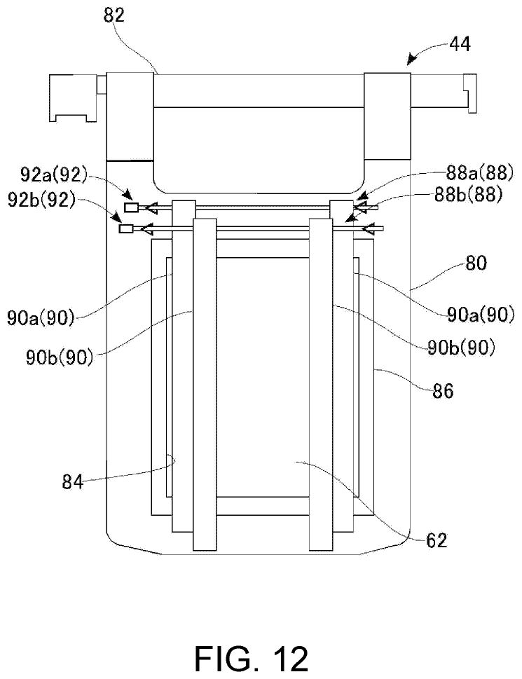

FIGS. 11 and 12 are front views of the anode holder 44 according to modification examples of the first embodiment. To simplify the description, the guide members 94 and the guide 108 (see FIG. 3) of the mask unit 88 will be omitted in the modification examples. Also, a form in which the drive mechanism 92 is secured to the anode holder 44 (holder main body 80) will be employed, and an overview of each component thereof will be described. (A) of FIG. 11 illustrates the anode holder 44 according to a first modification example, and (B) of FIG. 11 illustrates an anode holder 44 according to a second modification example. Also, FIG. 12 illustrates an anode holder 44 according to a third modification example.

As describe above in relation to FIG. 7, the first embodiment has been described on the assumption that the two longitudinal sides of the substrate W are the power supply sides 150. In the first modification example, the substrate contact points 142 may be disposed in such a form in which they follow the transverse sides of the first opening 120 and the second opening 124. In other words, the two transverse sides of the substrate W may be the power supply sides 150 while the two longitudinal sides are not the power supply sides 150. In this case, two mask members 90 extending in the transverse direction relative to the opening 84 of the anode holder 44 are disposed as illustrated in (A) of FIG. 11.

The positions of the mask members 90 can be changed by the drive mechanism 92 in the first modification example as well. The mask members 90 approach and are separated from each other in the direction that passes through the center of the opening 84 and is parallel to the axial line of the rod 100 by the drive mechanism 92. It is possible to curb the irregularity of the film thickness and to improve in-plane uniformity even in a case in which the power supply sides 150 (see FIG. 7) transversely extend, by configuring the mask unit 88 in this manner. Also, it is possible to effectively curb the irregularity of the film thickness by changing the positions of the mask members 90 even of the size and the like of the substrate W are changed.

Also, in the second modification example, the substrate contact points 142 may be disposed in such a form in which the substrate contact points follow all the sides of the first opening 120 and the second opening 124 (see FIG. 7). In other words, all the four sides of the substrate W may be the power supply sides 150. In this case, one mask member 90 is provided at a position corresponding to a location in which irregularity of the film thickness may be generated relative to one power supply sides 150, as illustrated in (B) of FIG. 11. In other words, two mask members 90 extending in the longitudinal directions and two mask members 90 extending in the transverse direction are disposed relative to the opening 84 of the anode holder 44.

The two mask members 90 extending in the longitudinal direction and the two mask members 90 extending in the transverse direction are disposed at mutually different positions relative to the direction that is perpendicular to the anode 62. It is possible to curb the irregularity of the film thickness and to improve in-plane uniformity even in the case in which four power supply sides 150 (see FIG. 7) are present, by configuring the mask unit 88 in this manner.

In the third modification example, two mask units 88 in which the mask members 90 extend in the same direction may be provided with respect to one anode holder 44. As illustrated in FIG. 12, mask units 88a and 88b are provided at different positions in the direction that is perpendicular to the anode 62 for the anode holder 4 in the third modification example. Both the mask members 90a and 90b extend in the longitudinal direction and are driven in the transverse direction by drive mechanisms 92a and 92b, respectively. Projection positions of the mask members 90a and 90b in the direction that is perpendicular to the anode 62 partially overlap each other.

As described above in the first embodiment, the positions and the degrees of the irregularity of the film thickness differ depending on the size, the shape, and the like of the substrate W in a case in which the substrate W as a target of the plating is changed while the inter-electrode distance is constantly maintained. It is possible to change the degree of overlapping of the projecting positions of the mask units 88 in the direction that is perpendicular to the anode 62 by providing two mask units 88 for one anode holder 44. In other words, it is possible to change the area (width) in which the mask member 90 covers the anode 62. It is thus possible to improve in-plane uniformity of the film thickness of various substrates W.

### Second Embodiment

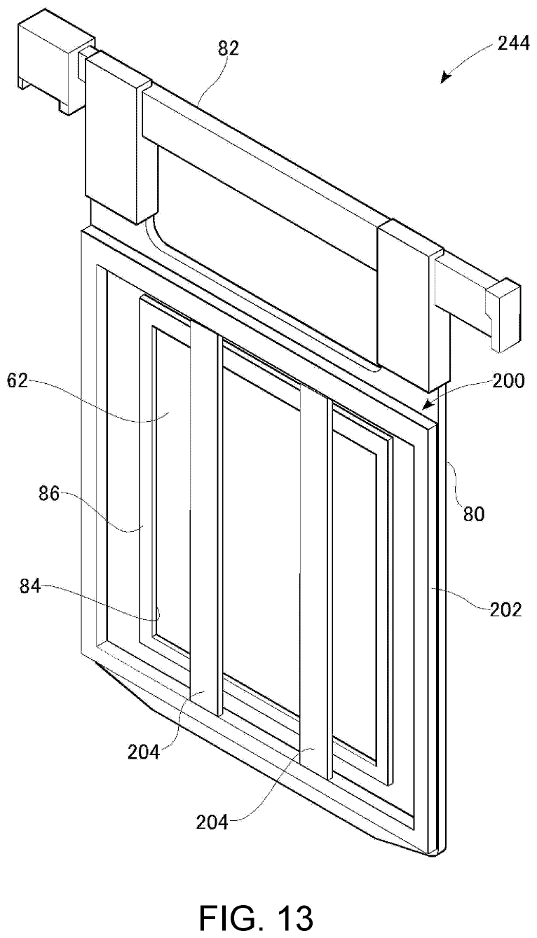

FIG. 13 is a perspective view of an anode holder 244 according to a second embodiment.

The second embodiment is different from the first embodiment in the shape of a mask unit 200. Hereinafter, portions that are different from those in the first embodiment will mainly be described.

The mask unit 200 has an attachment unit 202 with a frame shape and two mask members 204 with strip shapes. The mask members 204 extend parallel to the longitudinal sides of the opening 84 in such a form in which the mask members 204 bridge the upper side and the lower side of the opening 84 in the anode holder 244. The mask members 204 are included in the attachment unit 202 in such a form in which end surfaces thereof abut on the inner circumferential surface of the attachment unit 202. The mask unit 200 is not provided with a drive mechanism, and the mask members 204 are secured to the attachment unit 202. The attachment unit 202 is attached to the holder main body 80 with a securing member, which is not illustrated.

The mask members 204 are disposed parallel to the power supply sides 150 (see FIG. 7) of the substrate W in the second embodiment as well. It is possible to curb the irregularity of the film thickness of the substrate W in a case in which the inter-electrode distance is shorter than the optimal value and to improve in-plane uniformity in the second embodiment as well, by attaching such a mask unit 200 to the anode holder 244.

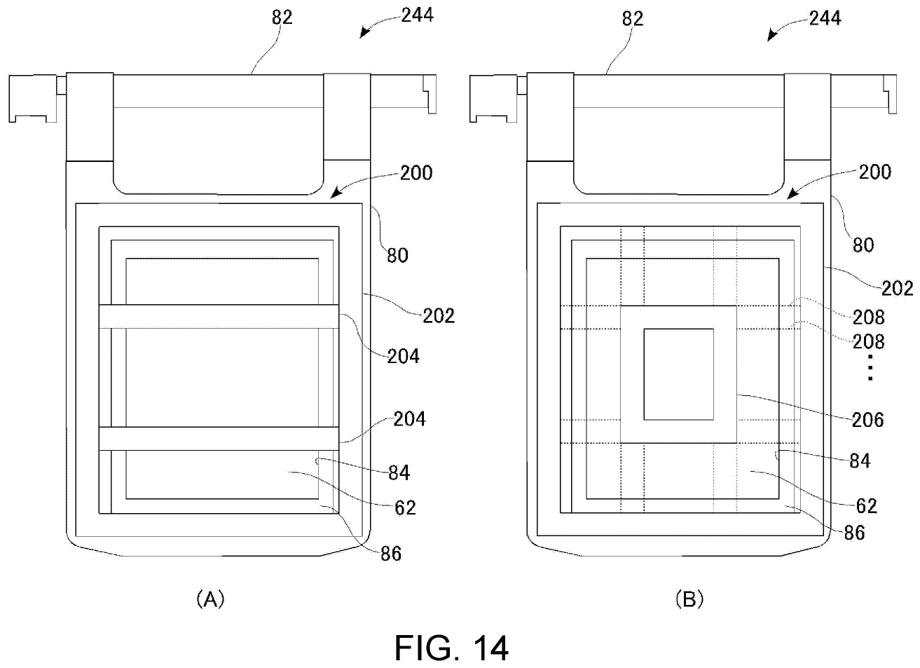

FIG. 14 is front view of anode holder 244 according to modification examples of the second embodiment. (A) of FIG. 14 illustrates an anode holder 244 according to a first modification example, and (B) of FIG. 14 illustrates an anode holder 244 according to a second modification example.

As described above in relation to FIG. 7, the first embodiment and the second embodiment have been described above on the assumption that two longitudinal sides of the substrate W are the power supply sides 150. In the first modification example, the substrate contact points 142 may be disposed in such a form in which the substrate contact points 142 follow the transverse sides of the first opening 120 (second opening 124). In other words, the two transverse sides of the substrate W may be the power supply sides 150 and the two longitudinal sides may not be the power supply sides 150. In this case, two mask members 204 are disposed in the transverse direction for the opening 84 of the anode holder 244 as illustrated in (A) of FIG. 14. It is possible to curb irregularity of the film thickness and to improve in-plane uniformity even in a case in which the power supply sides 150 (see FIG. 7) extend transversely, by configuring the mask unit 200 in this manner.

Also, in the second modification example, the substrate contact points 142 may be disposed in a form in which the substrate contact points 142 follow all the sides of the first opening 120 (second opening 124) (see FIG. 7). In other words, all the sides of the substrate W may be the power supply sides 150. The mask unit 200 as illustrated in (B) of FIG. 14 can be employed in this case.

The mask unit 200 illustrated in (B) of FIG. 14 has a mask member 206 with a rectangular shape. The mask member 206 is bridged with the coupling units 208 inside the attachment unit 202 in such a form in which the center thereof conforms to the center of the attachment unit 202. The coupling units 208 are made of bar-shaped members of a material that does not inhibit fields. The mask member 206 is disposed at a position corresponding to a location where irregularity of the film thickness may be generated. It is possible to curb the irregularity of the film thickness even in the case in which four power supply sides 150 (see FIG. 7) are present and to improve in-plane uniformity by configuring the mask unit 200 in this manner.

In this manner, a plurality of types of mask units 200 may be prepared and appropriately replaced in accordance with the size, the shape, and the like of the substrate W. It is thus possible to curb the irregularity of the film thickness of various substrates W while minimizing the change in inter-electrode distance. Alternatively, it is possible to curb the irregularity of the film thickness of various substrates W without changing the inter-electrode distance. It is thus possible to minimize the size of each plating tank 42 (see FIG. 2) and to realize space saving.

Although preferred embodiments of the present invention have been described above, it is needless to say that the present invention is not limited to the specific embodiments and various modifications can be made within the scope of the technical ideas of the present invention.

In the aforementioned embodiments, the form in which the anode mask is provided in the anode holder has been described. In a modification example, no anode mask may be provided, and the entire one surface of the anode may be exposed. Alternatively, the anode holder and the anode mask may be integrally molded.

In the aforementioned embodiments, a form in which the anode mask is screwed directly to the anode holder has been described. In the modification example, an insulating film such as an ion exchanging film may be provided between the anode holder and the anode mask. Providing the insulating film enables cations to be guided from the anode side to the substrate side (cathode side) without allowing additives and the like in the plating solution to penetrate therethrough in the plating processing.

In the aforementioned first embodiment, the substrate contact points are disposed on the sides (power supply sides) of the substrate that the substrate contact points face, along the entire region from ends on one side to ends on the other side of the sides. Also, a form in which the mask member is bridged to opposing sides of the openings of the anode holder is employed. In a modification example, the mask member may have such a length that it cannot be bridged across the opposing sides. In the second modification example of the second embodiment, for example, the mask member may be supported by the rod via the coupling units. In the case in which the substrate contact points face a part of the power supply sides, the mask member may have a length that is similar to that of the substrate contact points and may be provided at a position at which it faces the substrate contact points. It is possible to curb the film thickness at locations where irregularity of the film thickness may be generated and to prevent the film thickness from being excessively curbed in the vicinity thereof, by employing such a structure for the mask member. It is thus possible to improve in-plane uniformity.

In the aforementioned embodiments, examples of the irregularity of the film thickness of the substrate have been described. The locations and the degrees of the irregularity of the film thickness change depending on the size, the material, and the like of the substrate. The mask member may be disposed at any location as long as it is possible to curb the irregularity of the film thickness.

In the aforementioned first embodiment, the form in which two mask members 90 share one rod 100 has been employed, and the two mask members 90 are moved at the same time by the one drive mechanism 92. In a modification example, one drive mechanism may be connected to one mask member to individually control the mask members.

In the aforementioned first embodiment, the form in which the anode holder has the drive mechanism 92 including the motor 104 has been employed. In a modification example, the anode holder may have only a rod or a guide to move the mask members, and an actuator such as a motor or an air cylinder that serves as a power source for moving the mask members may be provided in the plating tank. For example, an output shaft of the actuator provided in the plating tank may be coupled to the rod to move the mask members.

In the aforementioned embodiments, the form in which the plating is performed on both the surfaces of the substrate has been described. In a modification example, plating may be performed only on one surface of the substrate. In this case, the anode may be provided at a position at which it faces the plated surface of the substrate and may not be provided at a position that faces the surface of the substrate on the opposite side of the plated surface.

Although the substrate holder is adapted to hold a square-shaped substrate in the aforementioned embodiments, the present invention is not limited thereto, and a substrate with a polygonal shape such as a hexagonal shape may be employed. In this case, the first opening 120 and the second opening 124 also have polygonal shapes. Also, the power supply sides are provided on mutually parallel sides among the sides of the substrate. It is possible to curb irregularity of the film thickness of the substrate and to improve in-plane uniformity even in a case of the substrate with a polygonal shape, by providing the mask members that are parallel to the power supply sides in the anode.

In the aforementioned embodiments, the mask members are provided at the positions at which they curb the irregularity of the film thickness of the substrate. In a modification example, the positions of the mask members may appropriately be set so as to be able to obtain a desired film thickness. For example, the mask members may be provided at positions corresponding to locations at which it is desired to reduce the film thickness of the substrate.

Note that the present invention is not limited to the aforementioned embodiments and modification examples and can be implemented by modifying components without departing from the gist thereof. Various inventions may be formed by appropriately combining the plurality of components disclosed in the aforementioned embodiments and modification examples. Also, some components may be deleted from all the components illustrated in the aforementioned embodiments and modification examples.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A plating method in which an anode holder adapted to hold a square-shaped anode and a substrate holder adapted to hold a square-shaped substrate are disposed to face each other in a plating tank and plating processing is performed on the substrate,
wherein the anode holder comprises
a holder main body having a square-shaped opening and adapted to hold the anode with a surface of the anode exposed from the opening, and
a mask adapted to cover a part of the anode inside the opening, and
a position covered with the mask is changed in accordance with the substrate.

2. A plating apparatus for performing plating processing on a square-shaped substrate comprising:
a plating tank;
an anode holder adapted to hold a square-shaped anode and disposed in the plating tank; and
a substrate holder adapted to hold the substrate and disposed to face the anode in the plating tank,
wherein the anode holder comprises
a holder main body having a square-shaped opening and adapted to hold the anode with a surface of the anode exposed from the opening, and
a mask adapted to cover a part of the anode inside the opening, and
the plating apparatus comprises a drive unit adapted to drive the mask to change a position of the mask relative to the opening.

3. An anode holder adapted to hold a square-shaped anode comprising:
a holder main body having a square-shaped opening and adapted to hold the anode with a surface of the anode exposed from the opening;
a mask adapted to cover a part of the anode on an inner side beyond an end of the opening; and
a drive unit adapted to drive the mask to change a position of the mask relative to the holder main body.

4. A plating apparatus for performing plating processing on a square-shaped substrate comprising:
a plating tank;
an anode holder adapted to hold a square-shaped anode and disposed in the plating tank; and
a substrate holder adapted to hold the substrate and disposed to face the anode in the plating tank,
wherein the anode holder comprises
a holder main body having a square-shaped opening and adapted to hold the anode with a surface of the anode exposed from the opening, and
a mask adapted to cover a part of the anode inside the opening, and
the substrate holder comprises contact points placed along sides of the substrate to supply a current to the substrate, and
the mask extends parallel to power supply sides that are the sides of the substrate, along which the contact points are aligned, and does not extend parallel to sides of the substrate that are not the power supply sides.

5. The plating apparatus according to claim 4, further comprising:
a first power supply side aligned on one of a pair of parallel sides of the substrate and a second power supply side aligned on the other side, as the power supply sides, and
wherein the mask comprises a first covering portion and a second covering portion that are parallel to the first power supply side and the second power supply side.

6. The plating apparatus according to claim 5, wherein the first covering portion and the second covering portion are disposed at symmetrical positions relative to a center line of the substrate that is parallel to the first power supply side and the second power supply side.
